(19) United States
(12) Patent Application Publication
(10) Pub. No.: US 2026/0348011 A1
(43) Pub. Date: Nov. 5, 2026

(54) DUAL NITROGEN FLOW CAPABILITY FOR METAL DEPOSITION

(71) Applicant: LAM RESEARCH CORPORATION, Fremont, CA (US)

(72) Inventors: Xiaolan BA, Fremont, CA (US); Zizhuo ZHANG, San Jose, CA (US); Juwen GAO, San Jose, CA (US); Sanjay GOPINATH, Fremont, CA (US); Ravi VELLANKI, San Jose, CA (US)

(21) Appl. No.: 19/125,433

(22) PCT Filed: Oct. 26, 2023
(86) PCT No.: PCT/US2023/035977

§ 371 Date: Apr. 29, 2025

Related U.S. Application Data
(60) Provisional application No. 63/421,751, filed on Nov. 2, 2022.

(51) Int. Cl. C23C 16/455; C23C 16/14; C23C 16/52; H10P 14/40; H10P 14/43

(52) U.S. Cl. CPC C23C 16/45561; C23C 16/14; C23C 16/45544; C23C 16/52; H10P 14/418; H10P 14/43

(57) ABSTRACT

A gas delivery system for a processing chamber includes a first flow path coupled to a reducing gas source and configured to supply a reducing gas from the reducing gas source to the processing chamber, a second flow path coupled to a precursor gas source and configured to supply a precursor gas from the precursor gas source to the processing chamber, a third flow path coupled to a first nitrogen gas source and configured to co-flow a first nitrogen gas into the processing chamber from the first nitrogen gas source at a same time that the reducing gas is supplied to the processing chamber, and a fourth flow path coupled to a second nitrogen gas source and configured to co-flow a second nitrogen gas into the processing chamber from the second nitrogen gas source at a same time that the precursor gas is supplied to the processing chamber.

### CROSS-REFERENCE TO RELATED APPLICATIONS

This application is a U.S. National Phase Application under 35 U.S.C. 371 of International Application No. PCT/US2023/035977, filed on Oct. 26, 2023, which claims the benefit of U.S. Provisional Application No. 63/421,751, filed on Nov. 2, 2022. The entire disclosures of the applications referenced above are incorporated herein by reference.

### FIELD

The present disclosure relates to substrate processing systems, and more particularly to substrate processing systems configured to perform metal deposition on substrates such as semiconductor wafers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film or other types of film using chemical vapor deposition (CVD), atomic layer deposition (ALD), and/or other deposition processes. During deposition, the substrate is arranged on a substrate support and one or more precursor gases may be supplied to a processing chamber during one or more process steps. Plasma may be used to initiate chemical reactions. After deposition is performed, the process gases are evacuated and the substrate is removed from the processing chamber.

In some examples, process gases used for deposition include tungsten. Tungsten-containing materials may be used to deposit semiconductor structures such as horizontal interconnects, vias between adjacent metal layers, contacts between metal layers, etc. Tungsten-containing materials may be used in some structures with complex patterning, such as 3D NAND structures with high aspect ratio features.

### SUMMARY

A gas delivery system for a processing chamber in a substrate processing system includes a first flow path coupled to a reducing gas source and configured to supply a reducing gas at a first flow rate from the reducing gas source to the processing chamber, a second flow path coupled to a precursor gas source and configured to supply a precursor gas at a second flow rate from the precursor gas source to the processing chamber, a third flow path coupled to a first nitrogen gas source and configured to co-flow a first nitrogen gas at a third flow rate into the processing chamber from the first nitrogen gas source at a same time that the reducing gas is supplied at the first flow rate to the processing chamber, and a fourth flow path coupled to a second nitrogen gas source and configured to co-flow a second nitrogen gas at a fourth flow rate into the processing chamber from the second nitrogen gas source at a same time that the precursor gas is supplied at the second flow rate to the processing chamber. The third flow rate of the first nitrogen gas is greater than the first flow rate of the reducing gas. The third flow rate of the first nitrogen gas is greater than the fourth flow rate of the second nitrogen gas.

In other features, the precursor gas is a metal-containing precursor gas. The precursor gas includes WF₆. The reducing gas includes molecular hydrogen. Each of the first nitrogen gas and the second nitrogen gas includes molecular nitrogen. Each of the first, second, third, and fourth flow paths includes at least one valve and a mass flow controller.

In other features, the first flow path includes a first valve coupled to the reducing gas source, a first mass flow controller coupled to the first valve, and a first manifold coupled between the first mass flow controller and the processing chamber, the second flow path includes a second valve coupled to the precursor gas source, a second mass flow controller coupled to the second valve, and a second manifold coupled between the second mass flow controller and the processing chamber, the third flow path includes a third valve coupled to the first nitrogen gas source, a third mass flow controller coupled to the third valve, and a third manifold coupled between the third mass flow controller and the processing chamber, and the fourth flow path includes a fourth valve coupled to the second nitrogen gas source, a fourth mass flow controller coupled to the fourth valve, and a fourth manifold coupled between the fourth mass flow controller and the processing chamber.

In other features, the third flow path is coupled to the first flow path between the first manifold and the processing chamber and the fourth flow path is coupled to the second flow path between the second manifold and the processing chamber. The gas delivery system of claim further includes a controller configured to control the first, second, third, and fourth valves and the first, second, third, and fourth mass flow controllers to co-flow the first nitrogen gas into the processing chamber with the reducing gas and co-flow the second nitrogen gas into the processing chamber with the precursor gas. The precursor gas is a metal-containing precursor gas, the reducing gas includes molecular hydrogen, and each of the first nitrogen gas and the second nitrogen gas includes molecular nitrogen. The processing chamber is configured to perform a metal deposition process. The metal-containing precursor gas includes WF₆. The controller is configured to control the gas delivery system such that the third flow rate of the first nitrogen gas that is co-flowed with the reducing gas is greater than the fourth flow rate of the second nitrogen gas that is co-flowed with the precursor gas and such that the third flow rate of the first nitrogen gas that is co-flowed with the reducing gas is greater than the first flow rate of the reducing gas.

A substrate processing system configured to perform a metal deposition process on a substrate arranged in a processing chamber includes a gas delivery system configured to separately supply each of a precursor gas, a reducing gas, a first nitrogen gas, and a second nitrogen gas to the processing chamber. A controller is configured to control the gas delivery system to perform a plurality of deposition cycles by controlling the gas delivery system to, in each of the deposition cycles, co-flow the first nitrogen gas with the reducing gas in a first dosing phase and co-flow the second nitrogen gas with the precursor gas in a second dosing phase.

In other features, the controller is configured to control the gas delivery system to co-flow the first nitrogen gas at a first flow rate with the reducing gas and to co-flow the second nitrogen gas at a second flow rate with the precursor gas and the first flow rate is greater than the second flow rate. The controller is configured to control the gas delivery system to co-flow the first nitrogen gas from a first nitrogen gas source and to co-flow the second nitrogen gas from a second nitrogen gas source separate from the first nitrogen gas source. The controller is configured to control the gas delivery system to selectively purge the processing chamber between the first dosing phase and the second dosing phase. The controller is configured to control the gas delivery system to co-flow the first nitrogen gas and the second nitrogen gas during each of nucleation layer deposition and bulk fill deposition of a metal-containing material. The precursor gas is WF₆, the reducing gas is molecular hydrogen, and each of the first nitrogen gas and the second nitrogen gas is molecular nitrogen.

A method for performing a deposition process to deposit a material on a substrate includes supplying, in a first dosing phase of a deposition cycle, a reducing gas to a processing chamber containing the substrate, and at a same time that the reducing gas is supplied to the processing chamber in the first dosing phase, co-flowing a first nitrogen gas with the reducing gas. Co-flowing the first nitrogen gas includes supplying the first nitrogen gas from a first nitrogen gas source. The method further includes supplying, in a second dosing phase of the deposition cycle subsequent to the first dosing phase, a precursor gas to the processing chamber and, at a same time that the precursor gas is supplied to the processing chamber in the second dosing phase, co-flowing a second nitrogen gas with the precursor gas. Co-flowing the second nitrogen gas includes supplying the second nitrogen gas from a second nitrogen gas source separate from the first nitrogen gas source. A flow rate of the first nitrogen gas in the first dosing phase is greater than a flow rate of the second nitrogen gas in the second dosing phase. The flow rate of the first nitrogen gas that is co-flowed with the reducing gas is greater than a flow rate of the reducing gas.

A gas delivery system for a processing chamber in a substrate processing system comprises a first flow path, a second flow path, and a third flow path. The first flow path is coupled to a reducing gas source and is configured to supply a reducing gas from the reducing gas source to the processing chamber. The second flow path is coupled to a precursor gas source and is configured to supply a precursor gas from the precursor gas source to the processing chamber. The third flow path is coupled to a nitrogen gas source and is configured to co-flow nitrogen gas into the processing chamber from the nitrogen gas source at a same time that the reducing gas is supplied to the processing chamber.

In other features, the third flow path is configured to not co-flow the nitrogen gas into the processing chamber when the precursor gas is supplied to the processing chamber.

In other features, the third flow path is configured to co-flow the nitrogen gas into the processing chamber only when the reducing gas is supplied to the processing chamber and to not co-flow the nitrogen gas into the processing chamber when the precursor gas is supplied to the processing chamber.

In other features, the first flow path is configured to supply the reducing gas at a first flow rate. The second flow path is configured to supply the precursor gas at a second flow rate. The third flow path is configured to co-flow nitrogen gas at a third flow rate that is greater than the first flow rate of the reducing gas.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2 is a functional block diagram of an example gas delivery system according to the present disclosure;

FIG. 3 illustrates example deposition cycles of a low fluorine tungsten deposition process according to the present disclosure; and

FIG. 4 illustrates steps of an example method of performing low fluorine tungsten deposition according to the present disclosure.

In the drawings, reference numbers may be reused to identify similar and/or identical elements.

### DETAILED DESCRIPTION

A substrate processing system and processing chamber may be configured to deposit tungsten (W) on a semiconductor substrate to form features such as vias, electrical contacts, metal layers, etc. For example, a tungsten nucleation layer is first deposited into a via or contact region. The tungsten nucleation layer may be deposited to conformally coat sidewalls and a bottom of the feature. Conforming to the sidewalls and bottom can be critical to support high quality deposition. In some examples, nucleation layers are deposited using atomic layer deposition (ALD) or pulsed nucleation layer (PNL) processes.

In ALD and PNL processes, pulses of reactants are sequentially injected and purged from the processing chamber (e.g., using alternating pulses of reactants and purge gases). A first reactant may be adsorbed onto the substrate and a second reactant reacts with the first reactant. The process is repeated in a cyclical manner until a desired deposition thickness is obtained.

Subsequent to deposition of the tungsten nucleation layer, bulk tungsten may be deposited (e.g., using a chemical vapor deposition (CVD) process) by reducing tungsten hexafluoride (WF₆) with a reducing agent such as molecular hydrogen (H₂). Bulk tungsten as used herein refers to tungsten used to fill most or all of a feature (e.g., at least about 50% of the feature). While a nucleation layer is a thin conformal film configured to facilitate subsequent formation of bulk material, bulk tungsten is configured to transmit current. Typically, bulk tungsten has a larger grain size and lower resistivity relative to a nucleation layer or film. In some examples, bulk tungsten is tungsten deposited to a thickness of at least 50 Å.

As semiconductor devices scale to smaller technology nodes and more complex patterning structures, achieving uniform conformal deposition may be difficult. Distribution of a material within a feature or structure may be characterized by a step coverage of the material. “Step coverage” is defined as a ratio of two thicknesses. For example, step coverage may refer to a thickness of the material inside the feature divided by the thickness of the material near an opening of the feature. “Inside the feature” may refer to a middle portion of the feature located at about a middle point of along a depth of the feature. In some examples, the middle portion corresponds to an area between about 25% and 75% of the distance or, in certain embodiments, between about 40% and 60% of the distance along the depth of the feature measured from the opening of the feature. In other examples, “inside the feature” corresponds to an end portion of the feature located between about 75% and 95% of a distance along the depth of the feature as measured from the opening. The “opening” of the feature corresponds to a top portion of the feature located within 25% or, more specifically, within 10% of an edge of the opening. Step coverage of over 100% can be obtained, for example, by filling a feature wider in the middle or near the bottom of the feature than at the feature opening.

Further, reducing a concentration or content of fluorine in the deposited tungsten film improves device performance. As feature size decreases, an amount of fluorine in the tungsten film has a greater effect on the performance of the device. For example, the thickness of the deposited tungsten film decreases as feature size decreases. As a result, fluorine is more likely to diffuse through thinner deposited tungsten films, which may cause failure of the device.

For some structures (e.g., 3D NAND structures), it is further desirable to decrease sidewall surface roughness of the features. Various techniques may be used to deposit tungsten having reduced roughness. For example, some substrate processing systems are configured to implement a low fluorine tungsten (LFW) deposition process to obtain smooth tungsten growth and improve step coverage.

In some examples, tungsten is deposited by flowing a carrier gas and alternately flowing a tungsten-containing precursor gas (e.g., WF₆) and a reducing gas (e.g., molecular hydrogen, or H₂) while flowing the carrier gas. A purge gas (e.g., an inert gas) may be supplied between pulses of the tungsten-containing precursor gas and the reducing gas. In some examples, nitrogen (e.g., molecular nitrogen, or N₂) is co-flowed with either the tungsten-containing precursor gas or the reducing gas to reduce sidewall surface roughness. The nitrogen facilitates occupation of surface bonding sites to improve surface mobility. An example LFW deposition technique that includes co-flowing nitrogen is described in more detail in U.S. Pat. Pub. No. 2021/0335617, the entirety of which is incorporated by reference herein.

LFW deposition systems and methods according to the present disclosure are configured to selectively co-flow nitrogen with either one of the tungsten-containing precursor gas, the reducing gas, or both. For example, different nitrogen sources are separately connected to respective tungsten-containing precursor gas and reducing gas flow paths and are controlled independently. As one example, flow rates and timing of the different nitrogen sources are separately controlled in both nucleation and bulk deposition steps. In other words, respective flow rates for co-flow of nitrogen with the tungsten-containing precursor gas and the reducing gas can be varied. In this manner, sidewall surface roughness and filling performance are improved.

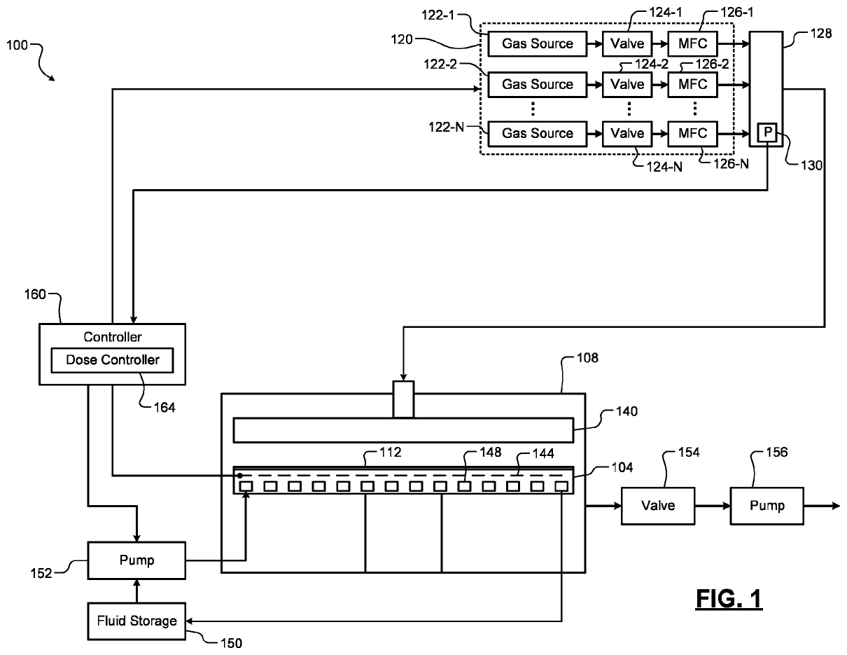

Referring now to FIG. 1, an example of a substrate processing system 100 including a substrate support (e.g., a pedestal configured for CVD and/or ALD deposition) 104 according to the present disclosure is shown. The substrate support 104 is arranged within a processing chamber 108. A substrate 112 is arranged on the substrate support 104 during processing. For example, deposition is performed on the substrate 112. The substrate 112 is removed and one or more additional substrates are treated.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. One or more pressure sensors 130 may be arranged in the manifold 128 to measure pressure. An output of the manifold 128 is supplied to a gas distribution device such as a multi-injector showerhead 140. While the manifold 128 is shown, multiple (e.g., two or more) manifolds may be used as described below in more detail.

In some examples, a temperature of the substrate support 104 may be controlled using resistive heaters 144. The substrate support 104 may include coolant channels 148. Cooling fluid is supplied to the coolant channels 148 from a fluid storage 150 using a pump 152. A valve 154 and a pump 156 may be used to evacuate reactants from the processing chamber 108 and/or to control pressure within the processing chamber 108.

A controller 160 includes a dose controller 164 that controls dosing provided by the multi-injector showerhead 140. The controller 160 also controls gas delivery from the gas delivery system 120. The controller 160 controls pressure in the processing chamber and/or evacuation of reactants using the valve 154 and the pump 156. The controller 160 controls the temperature of the substrate support 104 and the substrate 112 based upon temperature feedback (e.g., from sensors (not shown) in the substrate support and/or sensors (not shown) measuring coolant temperature).

In some examples, the substrate processing system 100 may be further configured to perform etching on the substrate 112 within the same processing chamber 108. Accordingly, the substrate processing system 100 may include components such as an RF generating system configured to generate and provide RF power to an upper and/or lower electrode, a matching and distribution network configured to generate plasma within the processing chamber 108 to etch the substrate 112, etc.

The substrate processing system 100 according to the present disclosure is configured to implement LFW deposition as described below in more detail. The gas delivery system 120 is configured to (e.g., responsive to the controller 160) independently co-flow nitrogen with either one of tungsten-containing precursor gas, a reducing gas, or both. For example, the gas sources 122 include two different nitrogen sources separately connected to respective tungsten-containing precursor gas and reducing gas flow path of the gas delivery system 120 as described below in more detail.

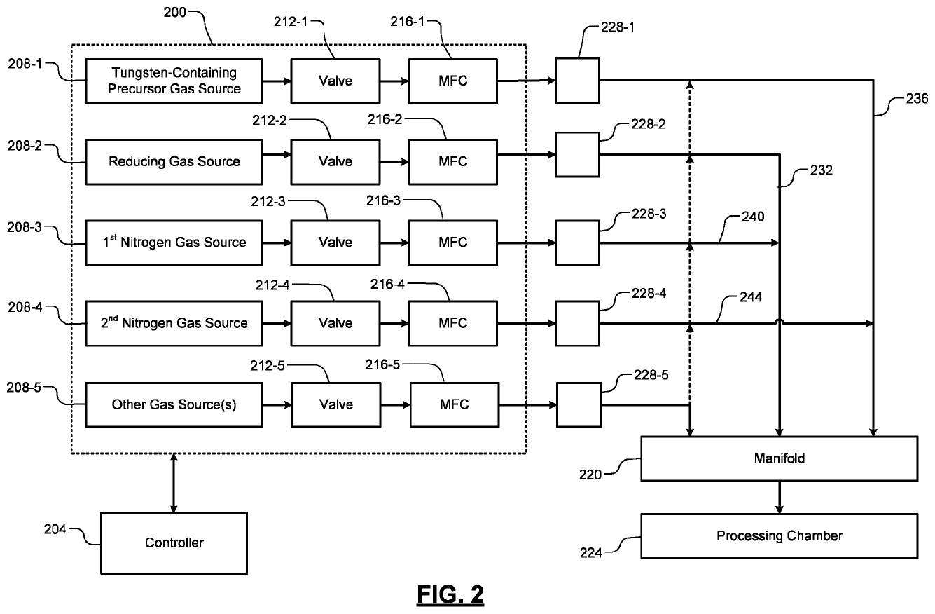

An example gas delivery system 200 and controller 204 according to the present disclosure are shown in FIG. 2. The gas delivery system 200 includes gas sources including but not limited to, a precursor gas (e.g., a tungsten-containing precursor gas such as WF₆) source 208-1, a reducing gas (e.g., H₂) source 208-2, a first nitrogen gas source 208-3, a second nitrogen gas source 208-4, and other gas sources (e.g., a carrier gas source, a purge gas source, etc.) 208-5 (collectively gas sources 208). While described herein with respect to WF₆, the principles of the present disclosure may also be implemented in LFW deposition processes that use other tungsten-containing gases. In some examples, other reducing gases may be used (e.g., a borane, silane, or germane gas). The gas sources 208 are coupled to respective valves 212-1, 212-2, 212-3, 212-4, and 212-5 (collectively valves 212) and mass flow controllers (MFCs) 216-1, 216-2, 216-3, 216-4, and 216-5 (collectively MFCs 216).

The MFCs 216 control flow of gases from the gas sources 208 to a manifold 220 where the gases are mixed. The mixed gases are supplied from the manifold 220 to a processing chamber 224 (e.g., via a gas distribution device such as a showerhead as described above in FIG. 1). As shown, respective manifolds 228-1, 228-2, 228-3, 228-4, and 228-5 (collectively the manifolds 228) may be disposed in each flow path between the gas sources 208 and the manifold 220. For simplicity, other components (e.g., additional valves in each of the flow paths, such as respective valves between the manifolds 228 and the manifold 220) are omitted.

The gas delivery system 200 and the controller 204 are configured to independently co-flow nitrogen from the first and second nitrogen gas sources 208-3 and 208-4 with one of the precursor gas from the precursor gas source 208-1, the reducing gas from the reducing gas source 208-2, or both. For example, the controller 204 is configured to control the valves 212, the MFCs 216, and other components to supply the carrier gas, the precursor gas, and the reducing gas to the processing chamber 224 to perform nucleation and bulk deposition of tungsten and further to selectively co-flow nitrogen with the precursor gas and the reducing gas.

For example, as shown, the first nitrogen gas source 208-3 is coupled to a flow path (e.g., a supply line 232) of the reducing gas. The second nitrogen gas source 208-4 is coupled to a flow path (e.g., a supply line 236) of the precursor gas. The controller 204 independently controls flow of nitrogen from the first nitrogen gas source 208-3 and the second nitrogen gas source 208-4 via respective ones of the valves 212 and MFCs 216. As shown, a flow path of the first nitrogen gas source 208-3 is configured for selective fluid communication with the supply line 232 via a supply line 240. A flow path of the second nitrogen gas source 208-4 is configured for selective fluid communication with the supply line 236 via a supply line 244. For example only, the controller 160 includes a dose controller (e.g., the dose controller 164 of FIG. 1) configured to independently control dosing of the precursor gas, the reducing gas, and the nitrogen from each of the nitrogen gas sources 208-3 and 208-4. In this manner, co-flow of nitrogen with the precursor gas and the reducing gas can be independently controlled throughout deposition processes.

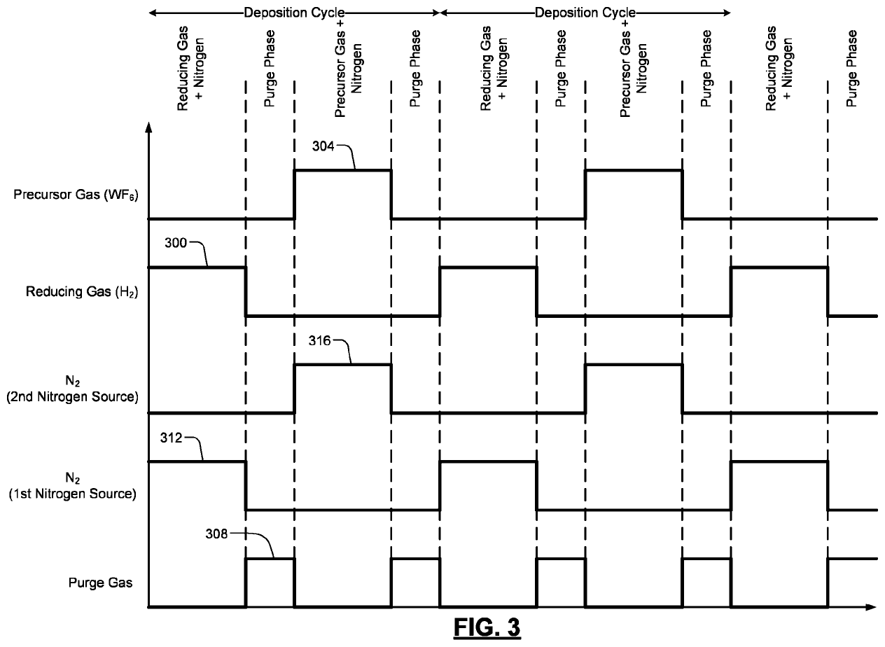

Referring now to FIG. 3 and with continued reference to FIG. 2, example deposition cycles of an LFW deposition process according to the present disclosure are described. The deposition cycles described in FIG. 3 may correspond to either nucleation or bulk fill deposition of tungsten-containing material.

As shown, each deposition cycle is comprised of a pair of alternating pulses of a reducing gas (e.g., H₂) as shown at 300 and a tungsten-containing precursor gas (e.g., WF₆) as shown at 304. In other words, a deposition cycle may include one reducing gas pulse and one precursor gas pulse. As shown at 308, pulses of a purge gas may be supplied in purge phases between the pulses of the reducing gas and the precursor gas and/or between deposition cycles. Although not shown in FIG. 3, a carrier gas may be continuously or periodically supplied during each deposition cycle.

As described above, the gas delivery system 200 is configured to co-flow nitrogen with both the reducing gas and the precursor gas. For example, in a first phase (e.g., a first dosing phase), each of the reducing gas and the nitrogen from the first nitrogen gas source 208-3 (i.e., a first nitrogen gas, as shown at 312) is pulsed (i.e., turned on) while the precursor gas and the nitrogen from the second nitrogen gas source 208-4 are off. In a second phase (e.g., a first purge phase), each of the reducing gas, the nitrogen from the first nitrogen gas source 208-3, the precursor gas, and the nitrogen from the second nitrogen gas source 208-4 is turned off and the purge gas is turned on.

In a third phase (e.g., a second dosing phase), each of the precursor gas and the nitrogen from the second nitrogen gas source 208-4 (i.e., a second nitrogen gas, as shown at 316) is pulsed (i.e., turned on) while each of the reducing gas and the nitrogen from the first nitrogen gas source 208-3 are off. In a fourth phase (e.g., a second purge phase), each of the reducing gas, the nitrogen from the first nitrogen gas source 208-3, the precursor gas, and the nitrogen from the second nitrogen gas source 208-4 is turned off and the purge gas is turned on. The first phase, the second phase, the third phase, and the fourth phase are repeated in subsequent deposition cycles.

As shown in FIG. 3, nitrogen is co-flowed with each reducing gas pulse and each precursor gas pulse, and in each deposition cycle, from the respective nitrogen sources. Further, nitrogen is co-flowed for the entirety of each reducing gas pulse and each precursor gas pulse. In other words, duty cycles of the reducing gas and the first nitrogen gas are approximately the same and duty cycles of the precursor gas and the second nitrogen gas are approximately the same. However, respective duty cycles (i.e., on and off times) of each of the reducing gas, the precursor gas, the first nitrogen gas, and the second nitrogen gas may be different, may be varied in each deposition cycle, etc.

In one example, the first nitrogen gas is co-flowed with the reducing gas in every deposition cycle while the second nitrogen gas is only co-flowed with the precursor gas in every other deposition cycle. In another example, the first nitrogen gas is co-flowed with the reducing gas in every other deposition cycle while the second nitrogen gas is co-flowed with the precursor gas in every deposition cycle. In other examples, the first nitrogen gas and/or the second nitrogen gas are only co-flowed during selected deposition cycles (e.g., during a first portion of a deposition process, during an end portion of a deposition process, etc.).

In other examples, durations and/or magnitudes of each pulse of the first nitrogen gas and the second nitrogen gas may be varied. For example, the first nitrogen gas and the second nitrogen gas may be pulsed during only a selected portion of each pulse of the reducing gas and the precursor gas, respectively. In another example, the first nitrogen gas and the second nitrogen gas are pulsed during an entirety of each pulse of the reducing gas and the precursor gas, respectively, but at different flow rates. In still other examples, flow rates of the first nitrogen gas and the second nitrogen gas may be varied from cycle to cycle.

In this manner, co-flow timing and rates of the first nitrogen gas and the second nitrogen gas can be varied to minimize sidewall surface roughness of the deposited tungsten-containing film. In one example, the co-flow rate of the first nitrogen gas with the reducing gas is greater than the co-flow rate of the second nitrogen gas with the precursor gas. For example, the co-flow rate of the first nitrogen gas is greater than 500 sccm. In an example, the co-flow rate of the first nitrogen gas is greater than a flow rate of the reducing gas (e.g., greater than 3000 sccm). Co-flowing the first nitrogen gas at a flow rate greater than both the flow rate of the reducing gas and the flow rate of the second nitrogen gas may reduce sidewall roughness by 40% or more.

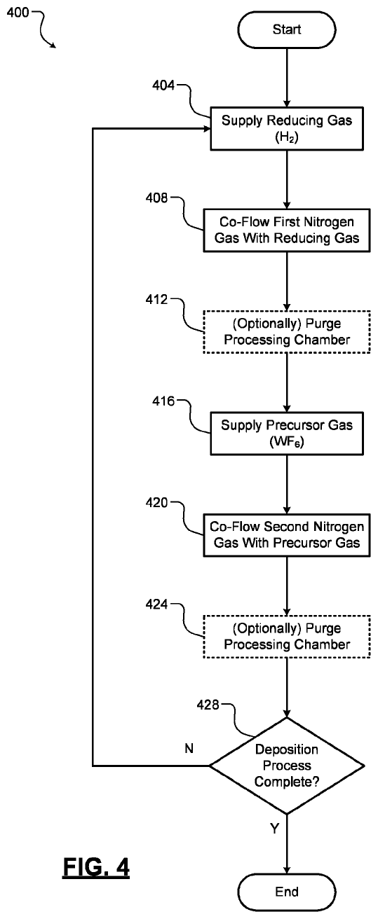

FIG. 4 illustrates steps of an example method 400 of performing low fluorine tungsten deposition according to the present disclosure. The method 400 as described may be applied to both nucleation layer deposition and bulk fill deposition processes. In some examples (e.g., for nucleation layer deposition), a tungsten-containing precursor gas may be supplied first in each deposition cycle and a reducing gas or agent is supplied subsequent to the tungsten-containing precursor. In other examples (e.g., for bulk tungsten deposition), the reducing gas is supplied first in each deposition cycle and the precursor gas is supplied subsequent to the reducing gas. As described below, each step of the method 400 may be performed using gas delivery system 200 and the controller 204 described in FIG. 2.

In the example shown in FIG. 4, a reducing gas is supplied to a processing chamber at 404 to expose a substrate to the reducing gas. At 408, a first nitrogen gas is supplied to the process chamber from a first nitrogen gas source. The first nitrogen gas supplied at 408 may occur at a same time as the reducing gas is supplied at 404 as described above with reference to FIG. 3. In an example, the first nitrogen gas is co-flowed at a flow rate greater than a flow rate of the reducing gas. The processing chamber is optionally purged at 412.

At 416, a tungsten-containing precursor gas is supplied to the processing chamber to expose the substrate to the precursor gas. At 420, a second nitrogen gas is supplied to the process chamber from a second nitrogen gas source. The second nitrogen gas supplied at 420 may occur at a same time as the precursor gas is supplied at 416 as described above with reference to FIG. 3. In an example, the second nitrogen gas is co-flowed at a flow rate less than a flow rate of the first nitrogen gas. In an example, the second nitrogen gas is co-flowed at a flow rate less than a flow rate of the first nitrogen gas but greater than a flow rate of the precursor gas. The processing chamber is optionally purged at 424.

At 428, the method 400 (e.g., the controller 204) determines whether the deposition process is complete. For example, the method 400 determines whether a predetermined number of deposition cycles have been completed such that a desired deposition thickness has been achieved. If true, the method 400 ends. If false, the method 400 continues to 404 to perform another deposition cycle.

The systems and methods of the present disclosure provide the following advantages. Typically, in LFW deposition processes, only one nitrogen gas source is shared with hydrogen and tungsten-containing precursor gas sources, which can only support one nitrogen gas flow with hydrogen or tungsten-containing precursor gas flow on each station (processing chamber). In contrast, in the systems and methods of the present disclosure, as described above, dual nitrogen gas sources are used for each station. Both hydrogen and tungsten-containing precursor gas flows have independent nitrogen gas flows during LFW deposition processes. With this flexibility, different nitrogen gas flows can be used with hydrogen and tungsten-containing precursor gas flows. Further, higher nitrogen gas flow with hydrogen gas flow and lower nitrogen gas flow with tungsten-containing precursor gas flow can reduce side-wall roughness significantly. Such nitrogen gas flows can occupy surface binding sites and improve surface mobility of hydrogen and/or tungsten-containing precursor gases. Thus, by providing the flexibility of nitrogen gas co-flow with hydrogen and/or tungsten-containing precursor gas flows at the same time in LFW nucleation and/or bulk fill deposition processes, and by independently controlling different nitrogen gas co-flows with hydrogen and tungsten-containing precursor gas flows during these processes, the systems and methods of the present disclosure improve tungsten sidewall roughness in LFW bulk fill deposition processes and improve filling performance.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A gas delivery system for a processing chamber in a substrate processing system, the gas delivery system comprising:
a first flow path coupled to a reducing gas source and configured to supply a reducing gas at a first flow rate from the reducing gas source to the processing chamber;
a second flow path coupled to a precursor gas source and configured to supply a precursor gas at a second flow rate from the precursor gas source to the processing chamber;
a third flow path coupled to a first nitrogen gas source and configured to co-flow a first nitrogen gas at a third flow rate into the processing chamber from the first nitrogen gas source at a same time that the reducing gas is supplied at the first flow rate to the processing chamber; and
a fourth flow path coupled to a second nitrogen gas source and configured to co-flow a second nitrogen gas at a fourth flow rate into the processing chamber from the second nitrogen gas source at a same time that the precursor gas is supplied at the second flow rate to the processing chamber;
wherein the third flow rate of the first nitrogen gas is greater than the first flow rate of the reducing gas; and
wherein the third flow rate of the first nitrogen gas is greater than the fourth flow rate of the second nitrogen gas.

2. The gas delivery system of claim 1, wherein the precursor gas is a metal-containing precursor gas.

3. The gas delivery system of claim 2, wherein the precursor gas includes WF₆.

4. The gas delivery system of claim 2, wherein the reducing gas includes molecular hydrogen.

5. The gas delivery system of claim 2, wherein each of the first nitrogen gas and the second nitrogen gas includes molecular nitrogen.

6. The gas delivery system of claim 1, wherein each of the first, second, third, and fourth flow paths includes at least one valve and a mass flow controller.

7. The gas delivery system of claim 6, wherein:
the first flow path includes a first valve coupled to the reducing gas source, a first mass flow controller coupled to the first valve, and a first manifold coupled between the first mass flow controller and the processing chamber;
the second flow path includes a second valve coupled to the precursor gas source, a second mass flow controller coupled to the second valve, and a second manifold coupled between the second mass flow controller and the processing chamber;
the third flow path includes a third valve coupled to the first nitrogen gas source, a third mass flow controller coupled to the third valve, and a third manifold coupled between the third mass flow controller and the processing chamber; and
the fourth flow path includes a fourth valve coupled to the second nitrogen gas source, a fourth mass flow controller coupled to the fourth valve, and a fourth manifold coupled between the fourth mass flow controller and the processing chamber.

8. The gas delivery system of claim 7, wherein:
the third flow path is coupled to the first flow path between the first manifold and the processing chamber; and
the fourth flow path is coupled to the second flow path between the second manifold and the processing chamber.

9. The gas delivery system of claim 7, further comprising a controller configured to control the first, second, third, and fourth valves and the first, second, third, and fourth mass flow controllers to co-flow the first nitrogen gas into the processing chamber with the reducing gas and co-flow the second nitrogen gas into the processing chamber with the precursor gas.

10. The gas delivery system of claim 7, wherein:
the precursor gas is a metal-containing precursor gas;
the reducing gas includes molecular hydrogen; and
each of the first nitrogen gas and the second nitrogen gas includes molecular nitrogen.

11. The gas delivery system of claim 10, wherein the processing chamber is configured to perform a metal deposition process.

12. The gas delivery system of claim 11, wherein the metal-containing precursor gas includes WF₆.

13. The gas delivery system of claim 9, wherein the controller is configured to control the gas delivery system such that the third flow rate of the first nitrogen gas that is co-flowed with the reducing gas is greater than the fourth flow rate of the second nitrogen gas that is co-flowed with the precursor gas and such that the third flow rate of the first nitrogen gas that is co-flowed with the reducing gas is greater than the first flow rate of the reducing gas.

14. A substrate processing system configured to perform a deposition process on a substrate arranged in a processing chamber, the substrate processing system comprising:
a gas delivery system configured to separately supply each of a precursor gas, a reducing gas, a first nitrogen gas, and a second nitrogen gas to the processing chamber; and
a controller configured to control the gas delivery system to perform a plurality of deposition cycles by controlling the gas delivery system to, in each of the deposition cycles,
co-flow the first nitrogen gas with the reducing gas in a first dosing phase, and
co-flow the second nitrogen gas with the precursor gas in a second dosing phase.

15. The substrate processing system of claim 14, wherein the controller is configured to control the gas delivery system to co-flow the first nitrogen gas at a first flow rate with the reducing gas and to co-flow the second nitrogen gas at a second flow rate with the precursor gas, and wherein the first flow rate is greater than the second flow rate.

16. The substrate processing system of claim 15, wherein the controller is configured to control the gas delivery system to co-flow the first nitrogen gas from a first nitrogen gas source and to co-flow the second nitrogen gas from a second nitrogen gas source separate from the first nitrogen gas source.

17. The substrate processing system of claim 14, wherein the controller is configured to control the gas delivery system to selectively purge the processing chamber between the first dosing phase and the second dosing phase.

18. The substrate processing system of claim 14, wherein the controller is configured to control the gas delivery system to co-flow the first nitrogen gas and the second nitrogen gas during each of nucleation layer deposition and bulk fill deposition of a metal-containing material.

19. The substrate processing system of claim 14, wherein the precursor gas is WF₆, the reducing gas is molecular hydrogen, and each of the first nitrogen gas and the second nitrogen gas is molecular nitrogen.

20. A method for performing a deposition process to deposit a material on a substrate, the method comprising:
supplying, in a first dosing phase of a deposition cycle, a reducing gas to a processing chamber containing the substrate;
at a same time that the reducing gas is supplied to the processing chamber in the first dosing phase, co-flowing a first nitrogen gas with the reducing gas, wherein co-flowing the first nitrogen gas includes supplying the first nitrogen gas from a first nitrogen gas source;
supplying, in a second dosing phase of the deposition cycle subsequent to the first dosing phase, a precursor gas to the processing chamber; and
at a same time that the precursor gas is supplied to the processing chamber in the second dosing phase, co-flowing a second nitrogen gas with the precursor gas, wherein co-flowing the second nitrogen gas includes supplying the second nitrogen gas from a second nitrogen gas source separate from the first nitrogen gas source,
wherein a flow rate of the first nitrogen gas in the first dosing phase is greater than a flow rate of the second nitrogen gas in the second dosing phase; and
wherein the flow rate of the first nitrogen gas that is co-flowed with the reducing gas is greater than a flow rate of the reducing gas.

21. A gas delivery system for a processing chamber in a substrate processing system, the gas delivery system comprising:
a first flow path coupled to a reducing gas source and configured to supply a reducing gas from the reducing gas source to the processing chamber;
a second flow path coupled to a precursor gas source and configured to supply a precursor gas from the precursor gas source to the processing chamber; and
a third flow path coupled to a nitrogen gas source and configured to co-flow nitrogen gas into the processing chamber from the nitrogen gas source at a same time that the reducing gas is supplied to the processing chamber.

22. The gas delivery system of claim 21 wherein the third flow path is configured to not co-flow the nitrogen gas into the processing chamber when the precursor gas is supplied to the processing chamber.

23. The gas delivery system of claim 21 wherein the third flow path is configured to co-flow the nitrogen gas into the processing chamber only when the reducing gas is supplied to the processing chamber and to not co-flow the nitrogen gas into the processing chamber when the precursor gas is supplied to the processing chamber.

24. The gas delivery system of claim 21 wherein:
the first flow path is configured to supply the reducing gas at a first flow rate;
the second flow path is configured to supply the precursor gas at a second flow rate; and
the third flow path is configured to co-flow nitrogen gas at a third flow rate that is greater than the first flow rate of the reducing gas.
